(19) United States
(12) Patent Application Publication
(10) Pub. No.: US 2026/0047422 A1
(43) Pub. Date: Feb. 12, 2026

(54) DIELECTRIC STACKS

(71) Applicant: QUALCOMM Incorporated, San Diego, CA (US)

(72) Inventors: Yan SUN, San Diego, CA (US); Shreesh NARASIMHA, Charlotte, NC (US)

(21) Appl. No.: 18/799,664

(22) Filed: Aug. 9, 2024

(51) Int. Cl. H01L 23/528; H01L 21/8234; H01L 27/092; H01L 29/06; H01L 29/08; H01L 29/423; H01L 29/66; H01L 29/775; H01L 29/78; H01L 29/786

(52) U.S. Cl. CPC H01L 23/5286; H10D 30/014; H10D 30/024; H10D 30/43; H10D 30/62; H10D 30/6735; H10D 30/6757; H10D 62/121; H10D 62/151; H10D 64/017; H10D 64/021; H10D 84/0149; H10D 84/038; H10D 84/853

(57) ABSTRACT

A chip includes a first epitaxial (epi) layer, a second epi layer, a gate between the first epi layer and the second epi layer, and one or more channels coupled between the first epi layer and the second epi layer, wherein the one or more channels pass through the gate. The chip also includes a dielectric stack under the gate, the dielectric stack including one or more first dielectric layers and one or more second dielectric layers.

### BACKGROUND

### Field

Aspects of the present disclosure relate generally to semiconductors, and more particularly, to dielectric stacks for facilitating backside processing.

### Background

A chip includes many active devices for performing various functions on the chip. The transistors may be implemented using gate-all-around field effect transistors (GAAFETs), fin field effect transistors (FinFETs), and/or other types of transistors. The chip may also include backside metal layers under the transistors. The backside metal layers may be patterned, for example, to provide a backside power distribution network (BSPDN) for delivering power to the transistors.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first epitaxial (epi) layer, a second epi layer, a gate between the first epi layer and the second epi layer, and one or more channels coupled between the first epi layer and the second epi layer, wherein the one or more channels pass through the gate. The chip also includes a dielectric stack under the gate, the dielectric stack including one or more first dielectric layers and one or more second dielectric layers.

A second aspect relates to a chip. The chip includes a first gate, a second gate, and an epitaxial (epi) layer between the first gate and the second gate. The chip also includes a first dielectric stack under the first gate and a second dielectric stack under the second gate. The first dielectric stack includes one or more first dielectric layers and one or more second dielectric layers. The second dielectric stack includes one or more third dielectric layers and one or more fourth dielectric layers. The chip also includes a backside contact extending between the first dielectric stack and the second dielectric stack, wherein the backside contact is coupled to a bottom surface of the first epi layer.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a gate-all-around FET according to certain aspects of the present disclosure.

FIG. 1C shows a perspective view of the transistor implemented with a FinFET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary structure including diffusion regions, gates, and a backside contact according to certain aspects of the present disclosure.

FIG. 3 shows an example of a cross-sectional view of the structure of FIG. 2 according to certain aspects of the present disclosure.

FIG. 4A shows an example in which a stack of alternating layers of silicon and silicon germanium is grown on a substrate according to certain aspects of the present disclosure.

FIG. 4B shows an example in which gate spacers and a sacrificial gate portion between the gate spacers are formed on the stack of FIG. 4A according to certain aspects of the present disclosure.

FIG. 4C show an example in which portions of the stack are etched away to form a vertical structure on the substrate according to certain aspects of the present disclosure.

FIG. 4D shows an example in which epitaxial (epi) layers are formed on opposite sides of the vertical structure of FIG. 4C according to certain aspects of the present disclosure

FIG. 4E shows an example in which the silicon germanium and the sacrificial gate portion are released according to certain aspects of the present disclosure.

FIG. 4F shows an example in which high-k dielectric and gate metal are deposited in spaces created by the removal of the silicon germanium and the sacrificial gate portion according to certain aspects of the present disclosure.

FIG. 5A shows an example in which the chip is flipped over for backside processing according to certain aspects of the present disclosure.

FIG. 5B shows an example of the chip after substrate removal during the backside processing according to certain aspects of the present disclosure.

FIG. 5C shows an example of formation of a backside interlayer dielectric (BS-ILD) on the chip according to certain aspects of the present disclosure.

FIG. 5D shows an example in which a trench is etched through the BS-ILD for a backside contact according to certain aspects of the present disclosure.

FIG. 5E shows an example in which misalignment of the trench of FIG. 5D causes the backside contact to short to a gate according to certain aspects of the present disclosure.

FIG. 6 shows an example of a cross-sectional view of the structure of FIG. 2 including a dielectric stack under a gate according to certain aspects of the present disclosure.

FIG. 7A shows an example in which a stack including silicon layers and silicon germanium layers is grown on a substrate according to certain aspects of the present disclosure.

FIG. 7B shows an example in which a sacrificial gate portion is formed on the stack of FIG. 7A according to certain aspects of the present disclosure.

FIG. 7C show an example of a first release process in which one or more of the silicon germanium layers in the stack are released to form one or more cavities according to certain aspects of the present disclosure.

FIG. 7D shows an example in which the one or more cavities of FIG. 7C are filled with gate spacer material according to certain aspects of the present disclosure.

FIG. 7E shows an example in which portions of the stack are etched away to form a vertical structure on the substrate according to certain aspects of the present disclosure.

FIG. 7F shows an example in which epitaxial (epi) layers are formed on opposite sides of the vertical structure of FIG. 7E according to certain aspects of the present disclosure

FIG. 7G shows an example in which the sacrificial gate portion is released to provide a space between the gate spacers and the remaining silicon germanium layers are released to provide one or more first cavities and one or more second cavities according to certain aspects of the present disclosure.

FIG. 7H shows an example in which high-k dielectric and gate metal are deposited in the space between the gate spacers and the one or more first cavities, and the high-k dielectric is deposited in the one or more second cavities according to certain aspects of the present disclosure.

FIG. 8A shows another example in which the chip is flipped over for backside processing according to certain aspects of the present disclosure.

FIG. 8B shows another example of the chip after substrate removal during the backside processing according to certain aspects of the present disclosure.

FIG. 8C shows another example of formation of a backside interlayer dielectric (BS-ILD) on the chip according to certain aspects of the present disclosure.

FIG. 8D shows another example in which a trench is etched through the BS-ILD for a backside contact according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

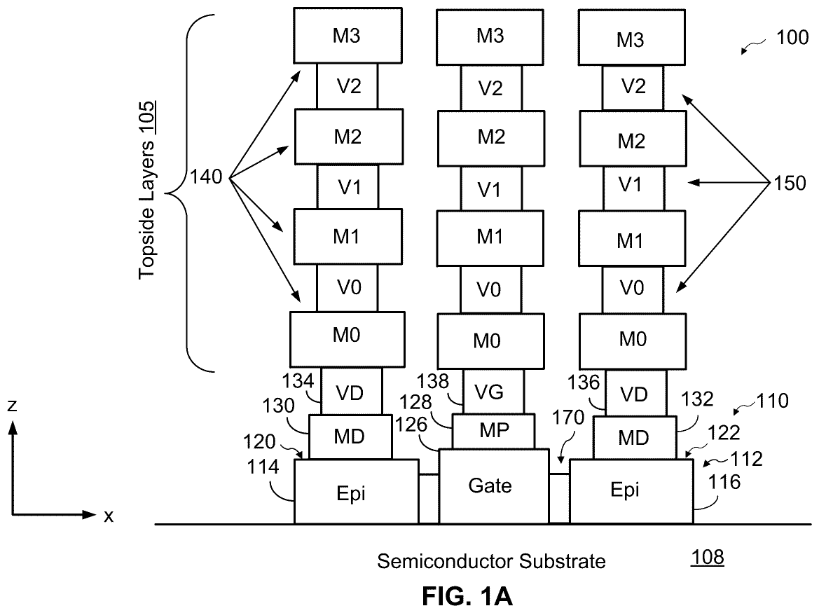

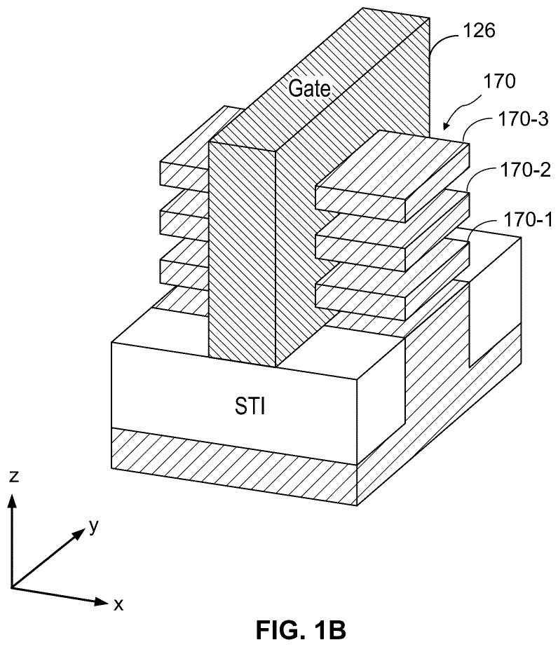

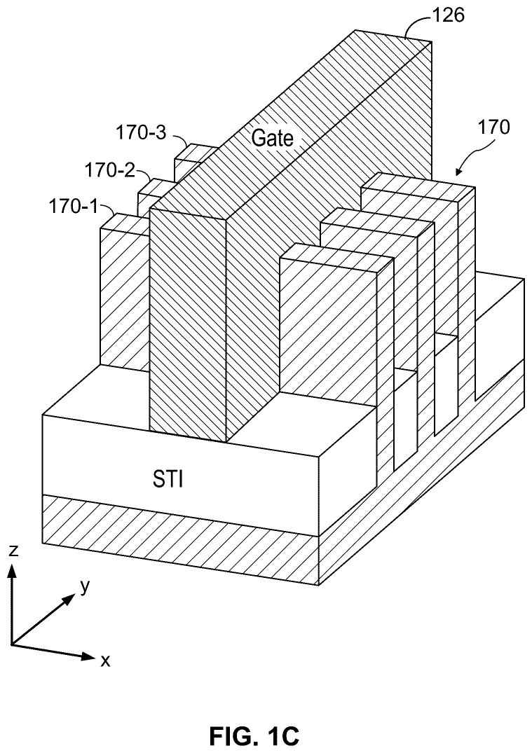

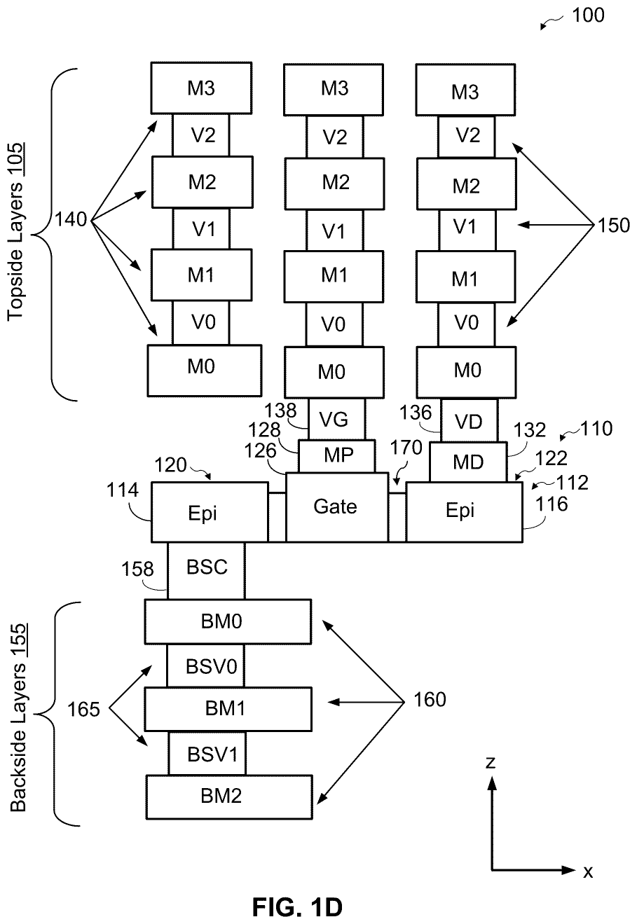

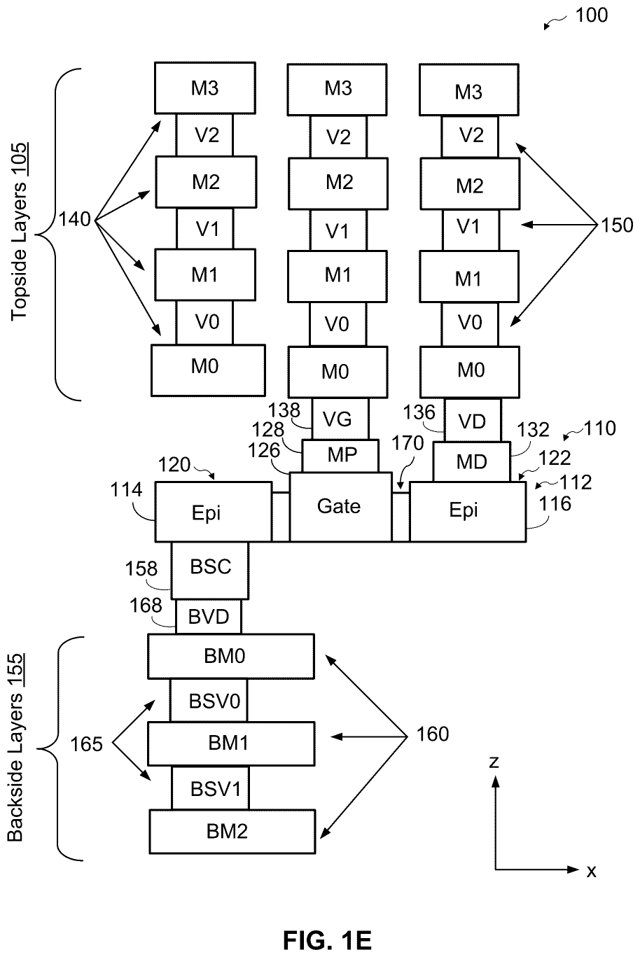

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel”is a structure that conducts current between a source and a drain of a transistor.

For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a gate-all-around FET process, the gate 126 may surround each of the one or more channels 170 (also referred as ribbons) on four sides. In this regard, FIG. 1B shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. In certain aspects, the chip 100 may include shallow trench isolation (STI) to reduce leakage between active devices on the chip 100. However, the STI may be omitted in some implementations.

For the example of a FinFET process, the gate 126 may surround each of the one or more channels 170 on three sides. In this regard, FIG. 1C shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown in FIG. 1A) between the gate 126 and the first epi layer 114 and a second spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail provides a supply voltage Vdd and may also be referred to as a power rail, a positive supply rail, a Vdd rail, or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V3. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 (labeled “VG”) disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 (labeled “VD”) disposed between the contact 130 and metal layer M0, in which the via 134 couples the contact 130 to metal layer M0. The chip 100 also includes a via 136 (labeled “VD”) disposed between the contact 132 and metal layer M0, in which the via 136 couples the contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to provide a circuit (e.g., an inverter, a driver, a logic gate, combinational logic, a latch, a flip-flop, a bit cell (e.g., a static random-access memory (SRAM) bit cell), or another type of circuit. The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell defined in the standard cell library may also be referred to as a standard cell.

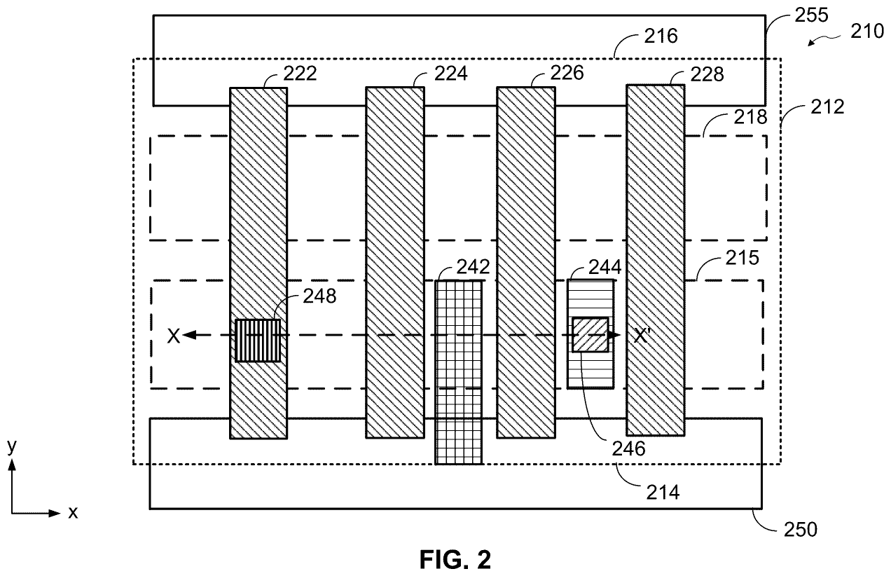

FIG. 2 shows a top view of an exemplary structure 210 on the chip 100 according to certain aspects. The structure 210 may be in a standard cell 212 in some implementations. In FIG. 2, the boundary of the cell 212 is shown in dotted line.

In this example, the structure 210 includes a first diffusion region 215 and a second diffusion region 218 extending in the x direction. The first diffusion region 215 may be a p-type diffusion region and the second diffusion region 218 may be an n-type diffusion region, or vice versa. For ease of illustration, the diffusion regions 215 and 218 are shown as rectangles in FIG. 2. The diffusion regions 215 and 218 may be isolated from the diffusion regions of adjacent cells (not shown) located in the same row as the cell 212 by diffusion breaks (not shown).

In this example, the structure 210 also includes gates 222, 224, 226, and 228 extending in the y direction. The gates 222, 224, 226, and 228 may be spaced apart in the x direction by a uniform pitch, as shown in the example in FIG. 2. Each of the gates 222, 224, 226, and 228 may include a gate metal (e.g., a high-k metal gate (HKMG)), polysilicon, and/or another gate material. It is to be appreciated that the structure 210 is not limited to the number of gates shown in the example in FIG. 2, and that the structure 210 may include a smaller number of gates or a larger number of gates.

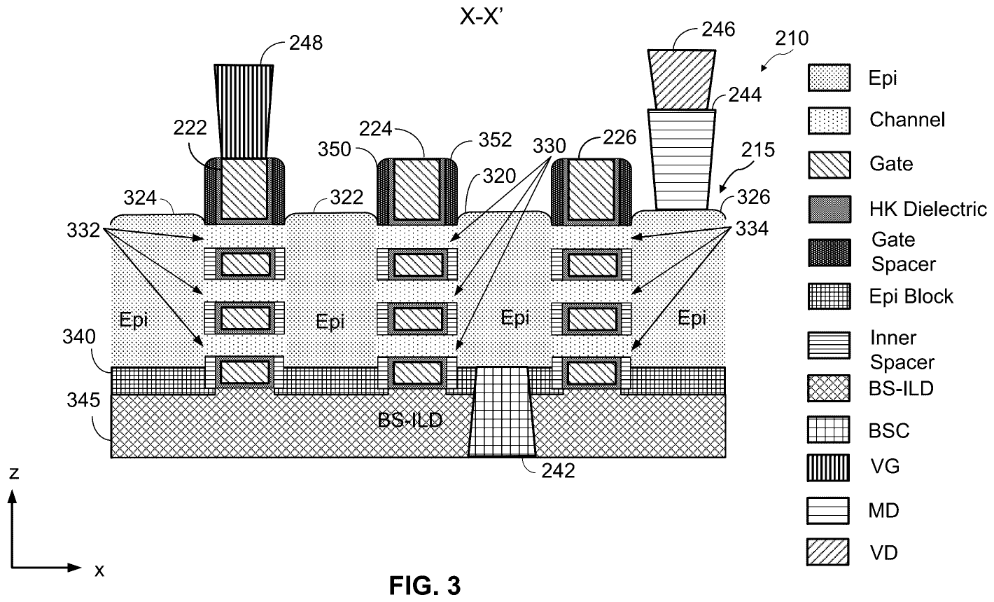

In this example, the first diffusion region 215 may include one or more channels extending in the x direction (e.g., the one or more channels 170) and one or more epi layers (e.g., the epi layers 114 and 116). Also, the second diffusion region 218 may include one or more channels extending in the x direction (e.g., the one or more channels 170) and one or more epi layers (e.g., the epi layers 114 and 116). Each channel may include a nanosheet, a nanowire, or another type of channel. Examples of epi layers and channels are shown in FIG. 3 discussed below.

FIG. 2 also shows an example of a first rail 250 and a second rail 255 formed from bottom metal layer BM0, which is below the gates 222, 224, 226, and 228 and the diffusion regions 215 and 218. In this example, each of the rails 250 and 255 extends in the x direction with a first edge 214 of the cell 212 overlapping the first rail 250 and a second edge 216 of the cell 212 overlapping the second rail 255. In this example, the first rail 250 may be a supply rail and the second rail 255 may be a ground rail, or vice versa. A ground rail may also be referred to as a Vss rail, a negative supply rail, or another term. The cell 212 may share the first rail 250 with an adjacent cell (not shown) abutting the first edge 214 of the cell 212, and the cell 212 may share the second rail 255 with another adjacent cell (not shown) abutting the second edge 216 of the cell 212. However, it is to be appreciated that the present disclosure is not limited to this example.

In the example in FIG. 2, the structure 210 includes a backside contact 242 (e.g., BSC in FIGS. 1D and 1E) disposed on a backside (i.e., bottom) surface of the first diffusion region 215. The backside contact 242 may be used, for example, to couple a first source/drain of the first diffusion region 215 to the first rail 250 in backside metal layer BM0 or signal routing in backside metal layer BM0.

The structure 210 may also include a frontside contact 244 (e.g., MD in FIGS. 1A, 1D and 1E) coupled to the first diffusion region 215 and a via 246 (e.g., VD in FIGS. 1A, 1D, and 1E) disposed on the frontside contact 244. The frontside contact 244 and the via 246 may be used, for example, to couple a second source/drain of the first diffusion region 215 to signal routing in metal layer M0 (shown in FIGS. 1A, 1D, and 1E). The structure 210 may also include a gate via 248 (e.g., VG in FIGS. 1A, 1D, and 1E) disposed on the gate 222. The gate via 248 may be used, for example, to couple the gate 222 to signal routing in metal layer M0. It is to be appreciated that the structure 210 may include one or more additional backside contacts, one or more additional frontside contacts, and/or one or more additional gate vias (e.g., depending on the circuit implemented by the cell 212).

FIG. 3 shows a cross-sectional view of the structure 210 taken along the cross-section line X-X′ in FIG. 2, which runs in the x direction and intersects the first diffusion region 215 and the gates 222, 224, and 226. In this example, the first diffusion region 215 includes a first epi layer 320 between the gates 224 and 226, a second epi layer 322 between the gates 222 and 224, a third epi layer 324 to the left of the gate 222, and a fourth epi layer 326 between the gates 226 and 228 (shown in FIG. 2). Each of the epi layers 320, 322, 324, and 326 provides a source/drain. It is to be appreciated that the first diffusion region 215 may include one or more additional epi layers.

The first diffusion region 215 also includes one or more channels 330 passing through the gate 224 and coupled between the first epi layer 320 and the second epi layer 322. The one or more channels 330 may include nanosheets, nanowires, or other types of channels. The gate 224 may include gate metal and a thin dielectric (e.g., high-k (HK) dielectric) surrounding the gate metal, as shown in the example in FIG. 3. The structure 210 may also include first inner spacers between the gate 224 and the first epi layer 320, and second inner spacers between the gate 224 and the second epi layer 322, as shown in the example in FIG. 3. The structure 210 may also include gate spacers 350 and 352 on opposite sides of a top portion of the gate 224 (e.g., to help isolate the gate 224 from source/drain contacts (e.g., MD in FIGS. 1A, 1D, and 1E)). In this example, the first diffusion region 215 may also include one or more channels 332 passing through the gate 222 and one or more channels 334 passing through the gate 226, as shown in the example in FIG. 3.

In the example in FIG. 3, the structure 210 also includes an epi block layer 340 disposed below the epi layers 320, 322, 324, and 326 (e.g., to block the epi layers 320, 322, 324, and 326 from growing from the substrate 108 during frontside processing). The epi block layer 340 may be omitted in some implementations. The structure 210 also includes a backside interlayer dielectric (BS-ILD) 345 under the epi block layer 340. The BS-ILD 345 may be formed during backside processing after removal of the substrate 108, as discussed further below. The BS-ILD 345 may include silicon oxide, silicon nitride, silicon carbon oxynitride (SiCON), or another dielectric material.

In the example in FIG. 3, the backside contact 242 (e.g., BSC in FIGS. 1D and 1E) is coupled to the bottom surface of the first epi layer 320. The backside contact 242 may be formed, for example, by etching a trench under the first epi layer 320 through the BS-ILD 345 and the epi block layer 340, and depositing contact metal in the trench. The backside contact 242 may be used, for example, to couple the first epi layer 320 to the first rail 250 (shown in FIG. 2) or signal routing in backside metal layer BM0 (shown in FIGS. 1D and 1E). For example, the backside contact 242 may be coupled between the bottom surface (i.e., backside surface) of the first epi layer 320 and the first rail 250 (shown in FIG. 2).

In the example in FIG. 3, the frontside contact 244 is coupled to the top surface of the fourth epi layer 326. The frontside contact 244 may be used, for example, to couple the fourth epi layer 326 to signal routing in metal layer M0 (shown in FIGS. 1A, 1D, and 1E).

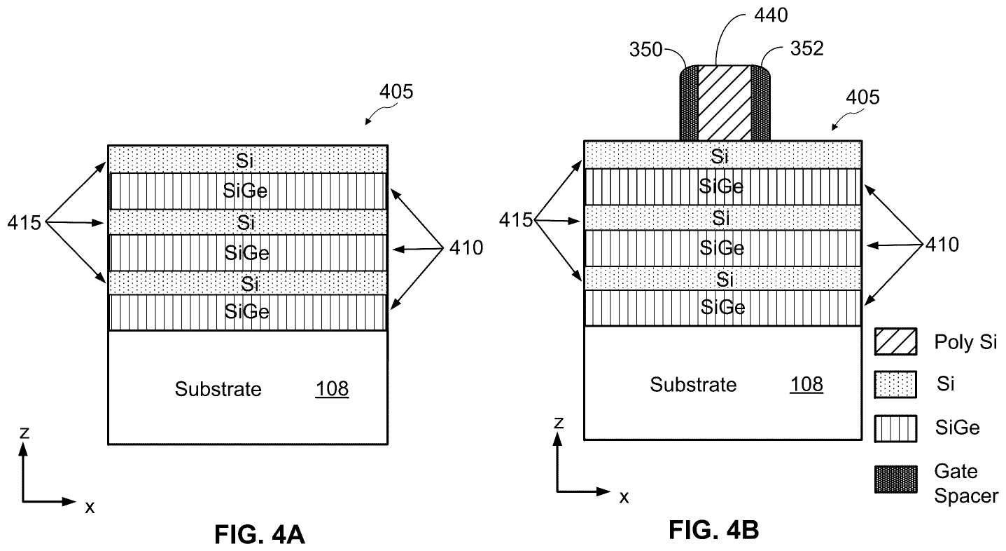

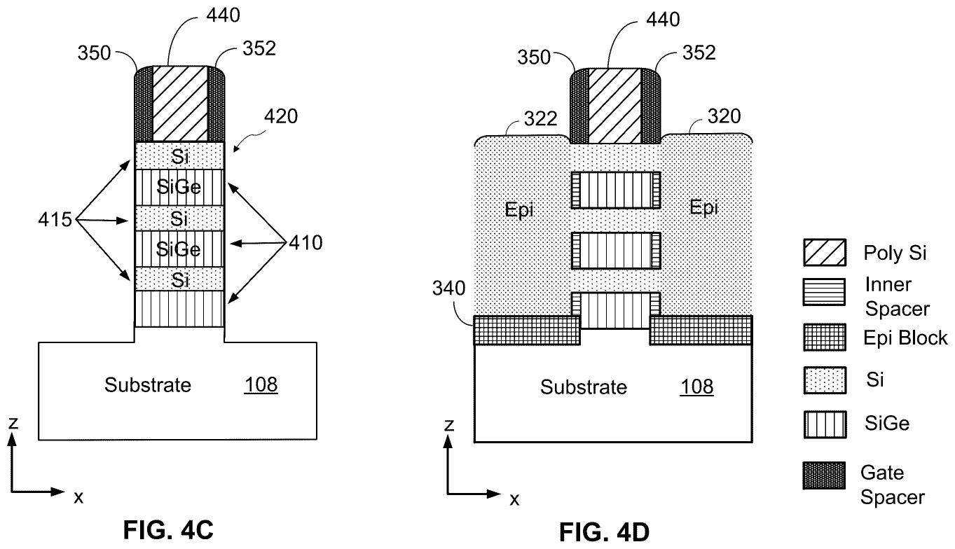

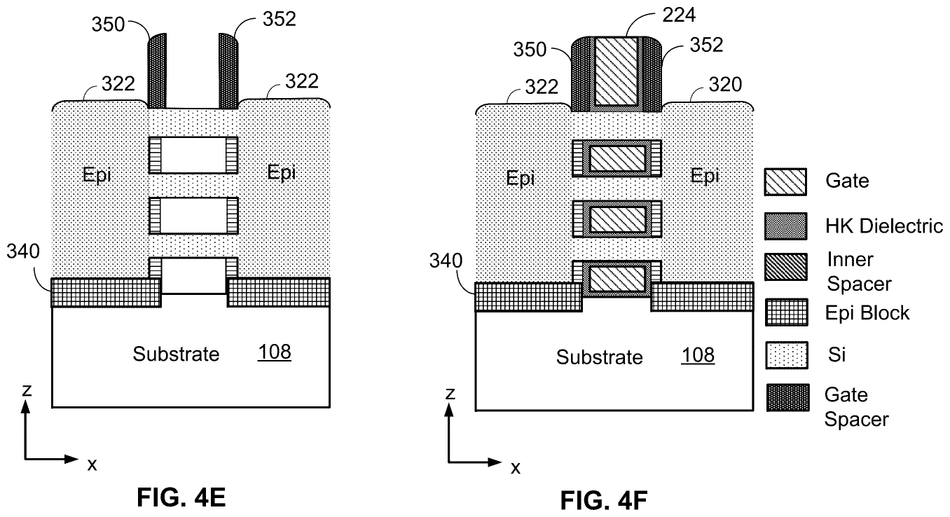

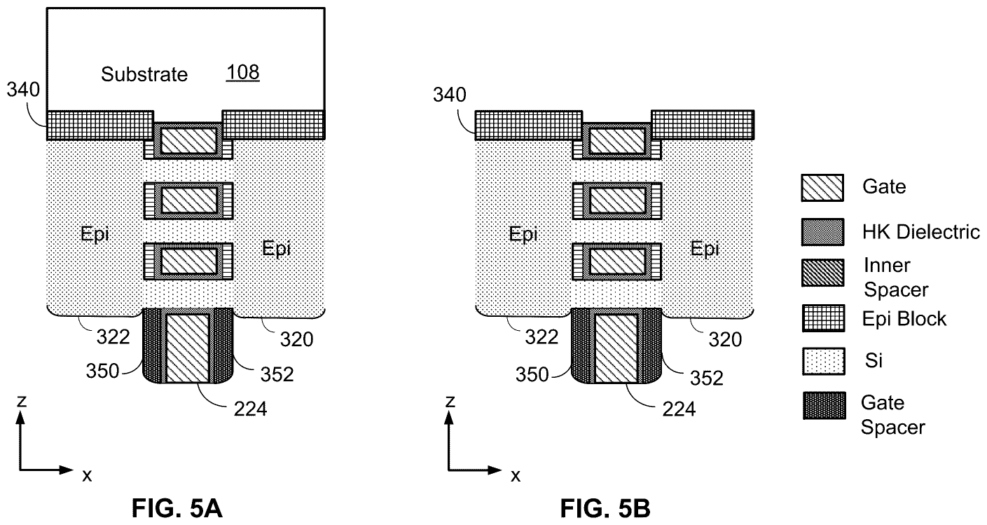

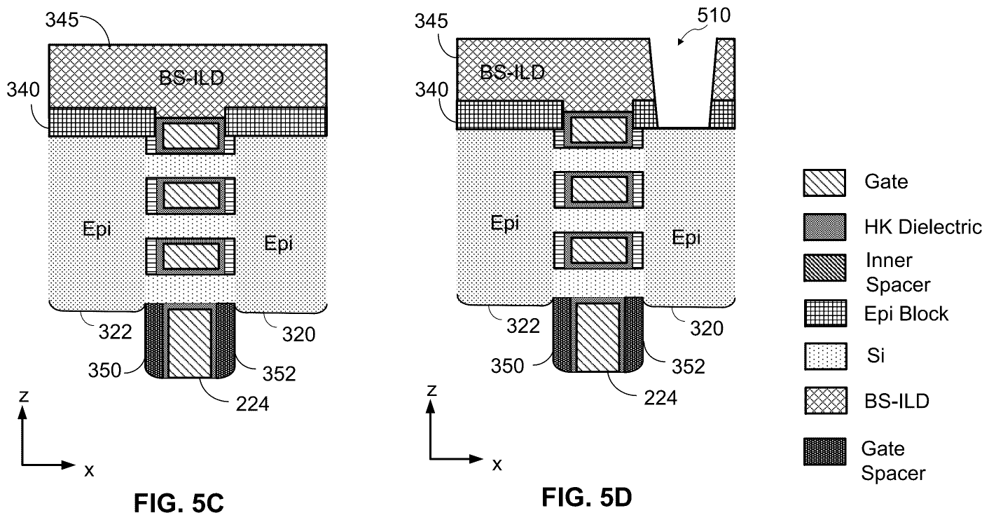

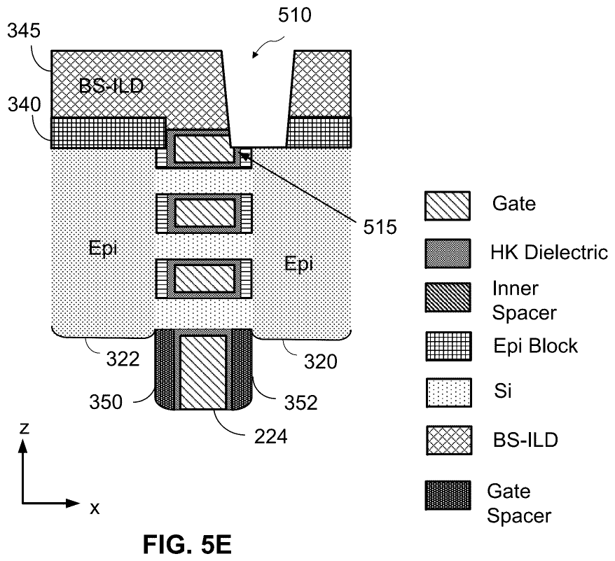

An exemplary frontside process and an exemplary backside process for forming the exemplary structure 210 in FIG. 3 will now be described with reference to FIGS. 4A to 4F and FIGS. 5A to 5D according to certain aspects. FIGS. 4A to 4F show the cross-sectional view of the exemplary structure 210 taken along the cross-section line X-X′ at different stages during the frontside processing. FIGS. 5A to 5D show the cross-sectional view of the exemplary structure 210 taken along the cross-section line X-X′ at different stages during the backside processing.

FIG. 4A shows an example of a stack 405 of silicon layers 415 and silicon germanium layers 410 grown on the substrate 108 (e.g., silicon substrate), in which the stack 405 alternates between the silicon layers 415 and the silicon germanium layers 410. The silicon layers 415 are used to form the one or more channels 330. The silicon germanium layers 410 are sacrificial layers that are released in a later process and replaced with gate metal to form the portions of the gate 224 between the one or more channels 330, as discussed further below. It is to be appreciated that the stack 405 is not limited to the number of silicon layers 415 and silicon germanium layers 410 shown in the example in FIG. 4A.

In FIG. 4B, a sacrificial gate portion 440 (e.g., polysilicon gate portion) is formed on the stack 405 and the gate spacers 350 and 352 are formed on opposite sides of the sacrificial gate portion 440. As discussed further below, the sacrificial gate portion 440 is removed in a later process and replaced with gate metal to form the top portion of the gate 224 between the gate spacers 350 and 352.

In FIG. 4C, portions of the stack 405 are etched away to form a vertical structure 420 including the silicon layers 415 and silicon germanium layers 410. The etching produces a space (i.e., recess) to the left of the vertical structure 420 and a space (i.e., recess) to the right of the vertical structure 420.

In FIG. 4D, the epi block layer 340 is deposited on the top surface of the substrate 108 in the space to the left of the vertical structure 420 and the space to the right of the vertical structure 420. In addition, the inner spacers for the gate 224 are formed on the sidewalls of the silicon germanium layers 410. Further, the first epi layer 320 is formed above the epi block layer 340 to the right of the vertical structure 420, and the second epi layer 322 is formed above the epi block layer 340 to the left of the vertical structure 420. Each of the epi layers 320 and 322 may be epitaxially grown, in which the epi block layer 340 blocks the epi layers 320 and 322 from growing from the substrate 108.

FIGS. 4E and 4F illustrate a replacement metal gate (RMG) process for replacing the silicon germanium layers 410 and the sacrificial gate portion 440 between the gate spacers 350 and 352 with gate metal. In this regard, FIG. 4E shows an example in which the silicon germanium layers 410 and the sacrificial gate portion 440 are released, producing a space (i.e., recess) between the gate spacers 350 and 352 and cavities between the inner spacers. FIG. 4F shows an example in which the high-k (HK) dielectric and the gate metal are deposited in the recess between the gate spacers 350 and 352 and the cavities between the inner spacers to form the gate 224.

After formation of the gate 224, the remaining frontside processing may be performed including formation of the frontside contacts (e.g., MD in FIGS. 1A, 1D, and 1E), the gate vias (e.g., VG in FIGS. 1A, 1D, and 1E), the source/drain vias (e.g., VD in FIGS. 1A, 1D, and 1E), and the topside layers 105.

After the frontside processing, a carrier wafer (not shown) may be bonded to the top of the chip 100 for structural support. The chip 100 may then be flipped to expose the backside of the semiconductor substrate 108, as shown in FIG. 5A. The semiconductor substrate 108 may then be removed in multiple steps which may include grinding, chemical mechanical polishing (CMP)), etching, and wet cleaning.

In this regard, FIG. 5B shows an example of the chip 100 after removal of the substrate 108. In this example, a large portion of the semiconductor substrate 108 is grounded off. After the grinding, a large portion of the remaining substrate is removed using the CMP. A challenge with the CMP is that a sufficient process window is needed to stop the CMP before the CMP reaches the active device (e.g., the gate 224 and the epi layers 320 and 322). After the CMP, the remaining substrate is etched away (e.g., using plasma etching or another type of etching process).

FIG. 5C shows an example in which the BS-ILD 345 is formed on the chip 100 after removal of the substrate 108. The BS-ILD 345 may include silicon oxide, silicon nitride, silicon carbon oxynitride (SiCON), or another dielectric material.

FIG. 5D shows an example of backside contact patterning in which a trench 510 is etched through the BS-ILD and the epi block layer 340 to reach the backside surface of the first epi layer 320. The trench 510 is then filled with contact metal to form the backside contact 242 (shown in FIG. 3). In some implementations, a silicide layer may be formed on the exposed backside surface of the first epi layer 320 (e.g., to reduce contact resistance) before filling the trench 510 with the contact metal.

A challenge with the backside contact patterning is alignment of the trench 510 with the first epi layer 320. Misalignment of the trench 510 may potentially cause the backside contact 242 to short to the gate 224. In this regard, FIG. 5E shows an example of misalignment in which the trench 510 is misaligned and exposes a portion 515 of the gate 224. In this example, the backside contact 242 (which is formed by filling the trench 510 with contact metal) contacts the gate 224 (and hence shorts to the gate 224), resulting in device failure.

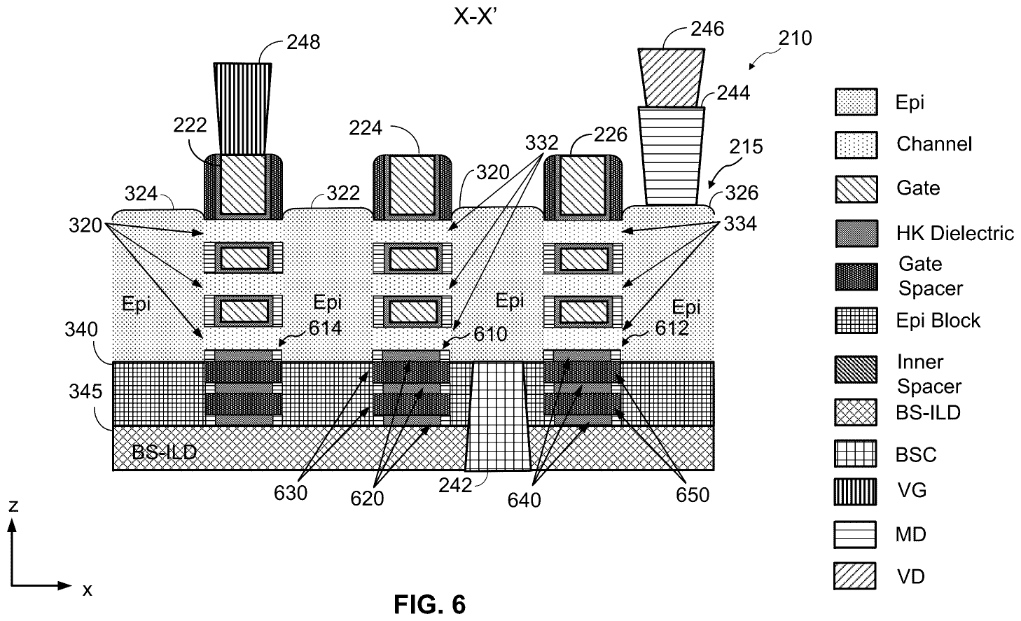

To address the above challenges, aspects of the present disclosure provide a dielectric stack 610 under the gate 224, as shown in FIG. 6. The dielectric stack 610 may be used, for example, to protect an active device (e.g., transistor) that includes the gate 224 from the substrate removal process by acting as a CMP stop and/or etch stop. The dielectric stack 610 may also be used, for example, to provide a hard mask for the backside contact patterning (e.g., to prevent the backside contact 242 from shorting to the gate 224 due to misalignment). The width of the dielectric stack 610 in the x direction may be approximately equal to the width of the gate 224 in the x direction.

In the example in FIG. 6, the dielectric stack 610 includes one or more first dielectric layers 620 and one or more second dielectric layers 630. In the example shown in FIG. 2, the one or more first dielectric layers 620 include three dielectric layers and the one or more second dielectric layers 630 includes two dielectric layers, in which the dielectric stack 610 alternates between the one or more first dielectric layers 620 and one or more second dielectric layers 630. However, it is to be appreciated that the present disclosure is not limited to this example. For example, in other implementations, the one or more first dielectric layers 620 may include one dielectric layer, two dielectric layers, or more than three dielectric layers. Also, in other implementations, the one or more second dielectric layers 630 may include one dielectric layer or more than two dielectric layers. In general, the number of dielectric layers in the dielectric stack 610 may be selected based on, for example, a desired height for the dielectric stack 610, cost, and/or process needs.

In the example shown in FIG. 6, the one or more first dielectric layers 620 include the high-k (HK) dielectric and the one or more second dielectric layers 630 include the gate spacer material (i.e., the same dielectric material used to form the gate spacers 350 and 352). However, it is to be appreciated that the present disclosure is not limited to this example. Examples of high-k (HK) dielectric materials that may be used include Hafnium Oxide (HfO₂), Zirconium Oxide (ZrO₂), Aluminum Oxide (Al₂O₃), Tantalum Pentoxide (Ta₂O₅), Lanthanum Oxide, Titanium oxide (TiO₂), Yttrium(III) Oxide (Y₂O₃), Lanthanum Doped Zirconium Oxide (LaZrO₂), etc. Examples of gate spacer materials that may be used include silicon nitride (SiN), silicon dioxide (SiO₂), silicon carbonitride (SiCN), silicon oxycarbonitride (SiOCN), carbon-doped silicon oxide (SiCOH), etc. Also, in the example in FIG. 6, the epi block layer 340 is thicker compared with the thickness of the epi block layer 340 in FIG. 3.

The structure 210 may also include a dielectric stack 612 under the gate 226 and a dielectric stack 614 under the gate 222. Each of the dielectric stacks 612 and 614 may have the same structure or substantially the same structure as the dielectric stack 610. For example, each of the dielectric stacks 612 and 614 may be a separate instance (i.e., copy) of the dielectric stack 610. In the example in FIG. 6, the dielectric stack 612 includes one or more third dielectric layers 640 and one or more fourth dielectric layers 650, in which the dielectric stack 612 alternates between the one or more third dielectric layers 640 and the one or more fourth dielectric layers 650. The one or more third dielectric layers 640 may include the high-k (HK) dielectric discussed above, and the one or more fourth dielectric layers 650 may include the gate spacer material discussed above. In the example in FIG. 6, the backside contact 242 extends between the dielectric stacks 610 and 612, and the width of the dielectric stack 612 in the x direction is approximately equal to the width of the gate 226 in the x direction.

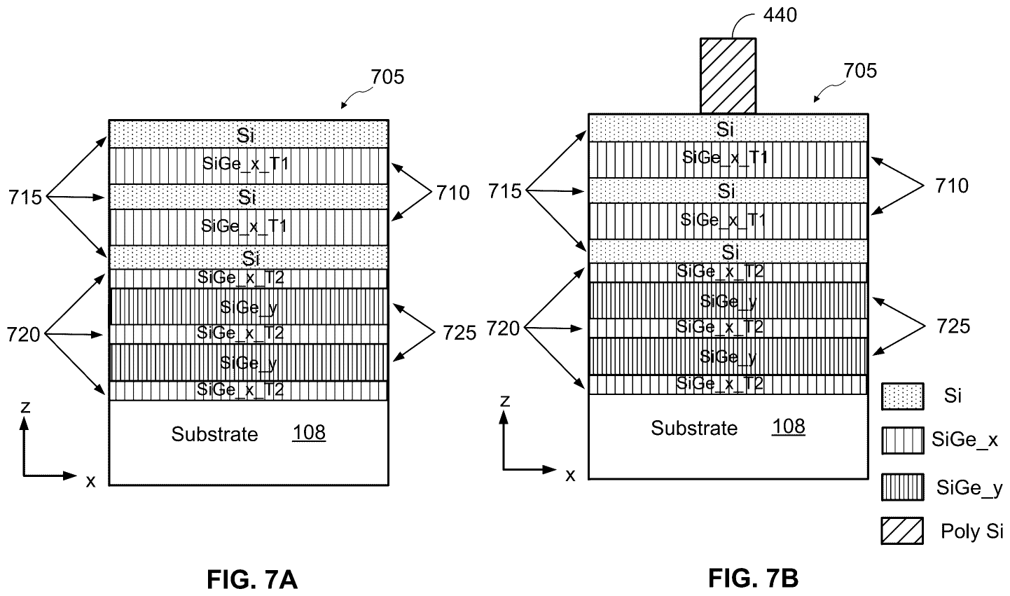

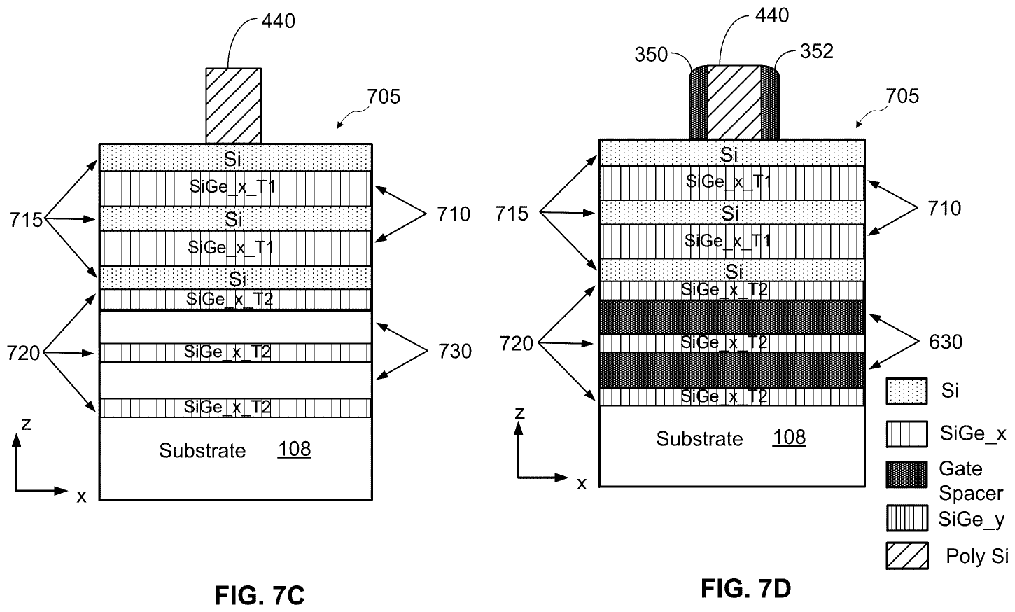

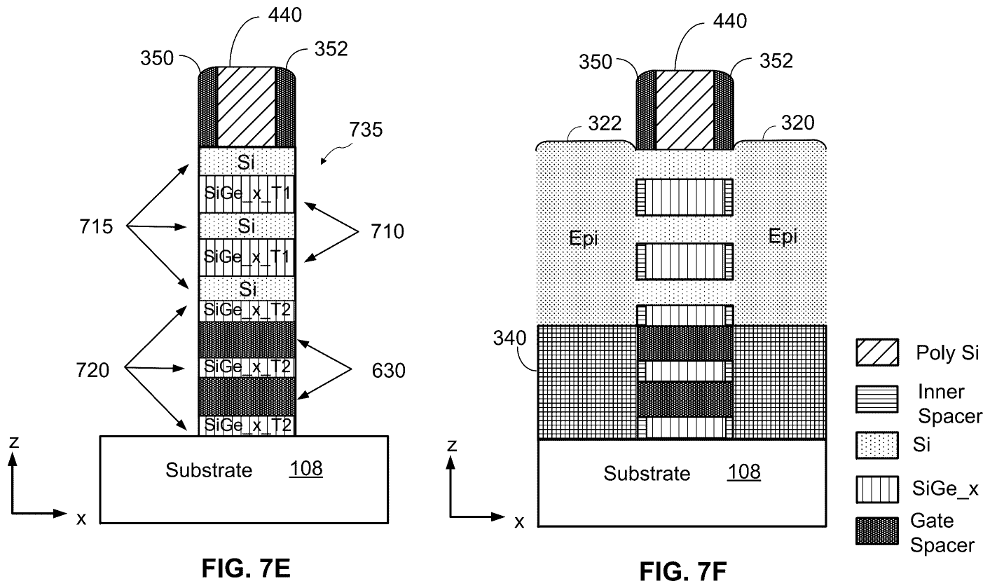

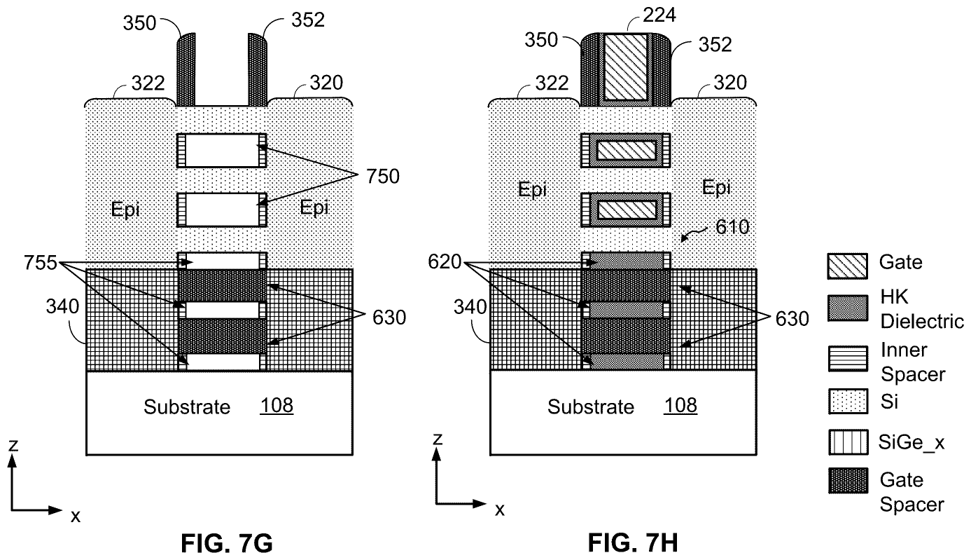

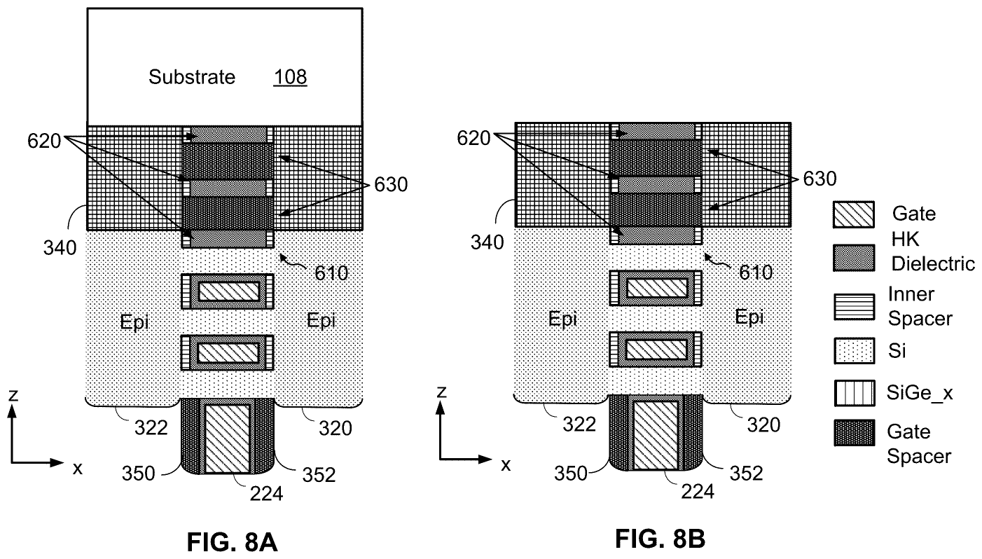

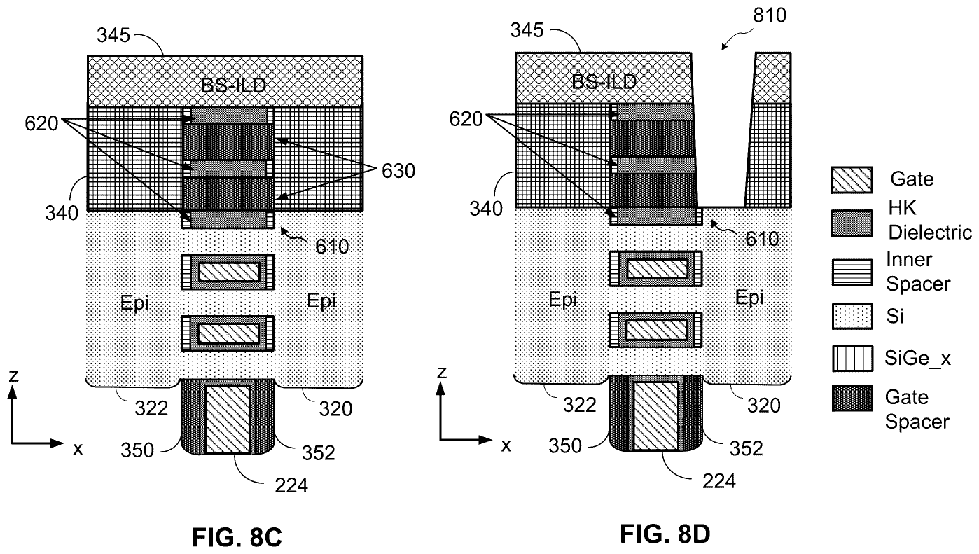

An exemplary frontside process and an exemplary backside process for forming the exemplary structure 210 in FIG. 6 will now be described with reference to FIGS. 7A to 7H and FIGS. 8A to 8D according to certain aspects. FIGS. 7A to 7H show the cross-sectional view of the exemplary structure 210 taken along the cross-section line X-X′ at different stages during the frontside processing. FIGS. 8A to 8D show the cross-sectional view of the exemplary structure 210 taken along the cross-section line X-X′ at different stages during the backside processing. The exemplary process for forming the dielectric stack 610 discussed below may also be used to form the dielectric stacks 612 and 614.

FIG. 7A shows an example of a stack 705 of silicon and silicon germanium layers grown on the substrate 108 according to certain aspects. The silicon and silicon germanium layers include one or more silicon layers 715, one or more first silicon germanium layers 710, one or more second silicon germanium layers 720, and one or more third silicon germanium layers 725. As discussed further below, the one or more silicon layers 715 are used to form the one or more channels 330, and the one or more first silicon germanium layers 710 are used to form portions of the gate 224 (e.g., using a RMG process in which the one or more first silicon germanium layers 710 are replaced with gate metal).

The one or more second silicon germanium layers 720 and the one or more third silicon germanium layers 725 are below the one or more silicon layers 715 and the one or more first silicon germanium layers 710. The one or more second silicon germanium layers 720 and the one or more third silicon germanium layers 725 are used to form the dielectric stack 610 under the gate 224. More particularly, the one or more second silicon germanium layers 720 are used to form the one or more first dielectric layers 620, and the one or more third silicon germanium layers 725 are used to form the one or more second dielectric layers 630, as discussed further below.

In the example in FIG. 7A, the one or more first silicon germanium layers 710 and the one or more second silicon germanium layers 720 have the same concentration of germanium (indicated by “x”) but different thicknesses. Each of the one or more first silicon germanium layers 710 has a thickness of T1 and each of the one or more second silicon germanium layers 720 has a thickness of T2 where T2 is less than T1. In certain aspects, the thickness T2 is equal to or less than twice the thickness of the high-k (HK) dielectric, as discussed further below.

Also, in this example, the one or more third silicon germanium layers 725 have a different concentration of germanium (indicated by “y”) than the one or more first silicon germanium layers 710 and the one or more second silicon germanium layers 720. The difference in the germanium concentrations allows the one or more third silicon germanium layers 725 to be released separately from the one or more first silicon germanium layers 710 and the one or more second silicon germanium layers 720, as discussed further below. For example, in some implementations, the one or more first silicon germanium layers 710 and the one or more second silicon germanium layers 720 may have a germanium concentration of between 15 and 20 percent, and the one or more third silicon germanium layers 725 may have a germanium concentration of between 40 and 45 percent. However, it is to be appreciated that the present disclosure is not limited to this example. In general, other germanium concentrations may be used.

In FIG. 7B, the sacrificial gate portion 440 (e.g., polysilicon gate portion) is formed on the stack 705.

In FIG. 7C, the one or more third silicon germanium layers 725 are released, which forms one or more cavities 730 in the stack 705. As discussed above, the higher concentration of germanium in the one or more third silicon germanium layers 725 allows the one or more third silicon germanium layers 725 to be released separately from the one or more first silicon germanium layers 710 and the one or more second silicon germanium layers 720.

In FIG. 7D, the gate spacers 350 and 352 are formed on opposite sides of the sacrificial gate portion 440. The gate spacers 350 and 352 may be formed by depositing gate spacer material on the stack 705 and patterning the gate spacer material (e.g., using lithographic and etching processes) to form the gate spacers 350 and 352.

In this example, the gate spacer material is also deposited into the one or more cavities 730 to form the one or more second dielectric layers 630 of the dielectric stack 610 (shown in FIG. 6). In certain aspects, the thickness of each of the one or more third silicon germanium layers 725 (and hence the height of each of the one or more cavities 730) may be equal to or less than twice the width of the gate spacers 350 and 352 in the x direction. This causes the gate spacer material to completely fill each of the one or more cavities 730, as shown in FIG. 7D. In this example, the layers of the stack 705 above the one or more second dielectric layers 630 help shield the one or more second dielectric layers from the directional etching process (e.g., plasma etch) used to form the gate spacers 350 and 352.

In FIG. 7E, portions of the stack 705 are etched away to form a vertical structure 735. The etching produces a space (i.e., recess) to the left of the vertical structure 735 and a space (i.e., recess) to the right of the vertical structure 735.

In FIG. 7F, the epi block layer 340 is deposited on the top surface of the substrate 108 in the space to the left of the vertical structure 735 and the space to the right of the vertical structure 735. The epi block layer 340 is thicker in this example compared with the thickness of the epi block layer 340 in FIG. 4D.

In addition, the inner spacers for the gate 224 are formed on the sidewalls of the one or more first silicon germanium layers 710 and the sidewalls of the one or more second silicon germanium layers 720. Further, the first epi layer 320 is formed above the epi block layer 340 to the right of the vertical structure 735, and the second epi layer 322 is formed above the epi block layer 340 to the left of the vertical structure 735. Each of the epi layers 320 and 322 may be epitaxially grown, in which the epi block layer 340 blocks the epi layers 320 and 322 from growing into the substrate 108.

FIG. 7G shows an example in which the one or more first silicon germanium layers 710 are released to produce one or more first cavities 750, and the one or more second silicon germanium layers 720 are released to provide one or more second cavities 755. The sacrificial gate portion 440 (shown in FIG. 7F) is also released to provide a space (i.e., recess) between the gate spacers 350 and 352.

FIG. 7H shows an example in which the high-k (HK) dielectric and the gate metal are deposited in the recess between the gate spacers 350 and 352 and the one or more first cavities 750 to form the gate 224. In certain aspects, the HK dielectric is deposited before the gate metal.

The HK dielectric is also deposited in the one or more second cavities 755 to form the one or more first dielectric layers 620 of the dielectric stack 610 under the gate 224. As discussed above, each of one or more second silicon germanium layers 720 has a thickness (i.e., T2 in FIG. 7A) that is equal to or less than twice the thickness of the HK dielectric in the gate 224. This causes the HK dielectric to completely fill the one or more second cavities 755 to form the one or more first dielectric layers 620.

After formation of the gate 224, the remaining frontside processing may be performed including formation of the frontside contacts (e.g., MD in FIGS. 1A, 1D, and 1E), the gate vias (e.g., VG in FIGS. 1A, 1D, and 1E), the source/drain vias (e.g., VD in FIGS. 1A, 1D, and 1E), and the topside layers 105.

After the frontside processing, a carrier wafer (not shown) may be bonded to the top of the chip 100 for structural support. The chip 100 may then be flipped to expose the backside of the semiconductor substrate 108, as shown in FIG. 8A. The semiconductor substrate 108 may then be removed in multiple steps which may include grinding, chemical mechanical polishing (CMP)), and etching.

In this regard, FIG. 8B shows an example of the chip 100 after removal of the substrate 108. In this example, a large portion of the semiconductor substrate 108 is grounded off. After the grinding, the remaining portion of the substrate is removed using CMP and etching.

In this example, the dielectric stack 610 keeps the CMP and the etching farther away from the active device (e.g., the gate 224 and the epi layers 322 and 320) compared with the example in FIG. 5B. This provides a larger process margin for stopping the CMP and the etching, which helps prevent the CMP and the etching from reaching and damaging the active device.

FIG. 8C shows an example in which the BS-ILD 345 is formed on the chip 100 after removal of the substrate 108. The BS-ILD 345 may include silicon oxide, silicon nitride, silicon carbon oxynitride (SiCON), or another dielectric material.

FIG. 8D shows an example of backside contact patterning in which a trench 810 is etched through the BS-ILD and the epi block layer 340 to reach the backside surface of the first epi layer 320. The trench 810 is then filled with contact metal to form the backside contact 242 (shown in FIG. 6).

FIG. 8D shows an example in which the trench 810 is misaligned. In this example, the dielectric stack 610 may serve as a hard mask for the etching process used to form the trench 810. This helps block the etching from reaching the gate 224 and shorting the backside contact 242 to the gate 224.

Implementation examples are described in the following numbered clauses:

1. A chip, comprising:
a first epitaxial (epi) layer;
a second epi layer;
a gate between the first epi layer and the second epi layer;
one or more channels coupled between the first epi layer and the second epi layer, wherein the one or more channels pass through the gate; and
a dielectric stack under the gate, the dielectric stack including:
   one or more first dielectric layers; and
   one or more second dielectric layers.

2. The chip of clause 1, further comprising a backside contact coupled to a bottom surface of the first epi layer.

3. The chip of clause 1 or 2, wherein the gate comprises a high-k (HK) dielectric material and a gate metal, and each of the one or more first dielectric layers comprises the HK dielectric material.

4. The chip of clause 3, wherein a thickness of each of the one or more first dielectric layers is equal to or less than twice a thickness of the HK dielectric material in the gate.

5. The chip of clause 3 or 4, wherein the HK dielectric material comprises at least one of Hafnium Oxide (HfO₂), Zirconium Oxide (ZrO₂), Aluminum Oxide (Al₂O₃), Tantalum Pentoxide (Ta₂O₅), Lanthanum Oxide, Titanium oxide (TiO₂), Yttrium(III) Oxide (Y₂O₃), and Lanthanum Doped Zirconium Oxide (LaZrO₂).

6. The chip of any one of clauses 1 to 5, further comprising:
a first gate spacer; and
a second gate spacer, wherein a portion of the gate is disposed between the first gate spacer and the second gate spacer.

7. The chip of clause 6, wherein each of the one or more second dielectric layers comprises a same dielectric material as the first gate spacer and the second gate spacer.

8. The chip of clause 7, wherein the dielectric material comprises at least one of silicon nitride (SiN), silicon dioxide (SiO₂), silicon carbonitride (SiCN), silicon oxycarbonitride (SiOCN), and carbon-doped silicon oxide (SiCOH).

9. The chip of any one of clauses 1 to 8, wherein the one or more first dielectric layers comprise two or more first dielectric layers, the one or more second dielectric layers comprise two or more second dielectric layers, and the dielectric stack alternates between the two or more first dielectric layers and the two or more second dielectric layers.

10. The chip of any one of clauses 1 to 9, wherein a width of the gate is approximately equal to a width of the dielectric stack.

11. The chip of any one of clauses 1 to 10, further comprising a backside interlayer dielectric (BS-ILD) extending under the dielectric stack and the first epi layer.

12. The chip of clause 11, further comprising a backside contact extending through the BS-ILD, wherein the backside contact is coupled to a bottom surface of the first epi layer.

13. The chip of clause 12, further comprising an epi block layer disposed between the first epi layer and the BS-ILD, wherein the backside contact extends through the epi block layer.

14. The chip of clause 12 or 13, further comprising a backside rail, wherein the backside contact is coupled between the bottom surface of the first epi layer and the backside rail.

15. The chip of clause 14, wherein the backside rail comprises a positive supply rail or a ground rail.

16. A chip, comprising:
a first gate;
a second gate;
an epitaxial (epi) layer between the first gate and the second gate;
a first dielectric stack under the first gate, the first dielectric stack including:
   one or more first dielectric layers; and
   one or more second dielectric layers;
a second dielectric stack under the second gate, the second dielectric stack including:
   one or more third dielectric layers; and
   one or more fourth dielectric layers; and
a backside contact extending between the first dielectric stack and the second dielectric stack, wherein the backside contact is coupled to a bottom surface of the first epi layer.

17. The chip of clause 16, wherein each of the first gate and the second gate comprises a high-k (HK) dielectric material and a gate metal, and each of the one or more first dielectric layers and each of the one or more third dielectric layers comprises the HK dielectric material.

18. The chip of clause 17, wherein the HK dielectric material comprises at least one of Hafnium Oxide (HfO₂), Zirconium Oxide (ZrO₂), Aluminum Oxide (Al₂O₃), Tantalum Pentoxide (Ta₂O₅), Lanthanum Oxide, Titanium oxide (TiO₂), Yttrium(III) Oxide (Y₂O₃), and Lanthanum Doped Zirconium Oxide (LaZrO₂).

19. The chip of any one of clauses 16 to 18, further comprising:
a first gate spacer; and
a second gate spacer, wherein a portion of the first gate is disposed between the first gate spacer and the second gate spacer.

20. The chip of clause 19, wherein each of the one or more second dielectric layers and each of the one or more fourth dielectric layers comprises a same dielectric material as the first gate spacer and the second gate spacer.

21. The chip of clause 20, wherein the dielectric material comprises at least one of silicon nitride (SiN), silicon dioxide (SiO₂), silicon carbonitride (SiCN), silicon oxycarbonitride (SiOCN), and carbon-doped silicon oxide (SiCOH).

22. The chip of any one of clauses 16 to 21, wherein a width of the first gate is approximately equal to a width of the first dielectric stack, and a width of the second gate is approximately equal to a width of the second dielectric stack.

23. The chip of any one of clauses 16 to 22, wherein the one or more first dielectric layers comprise two or more first dielectric layers, the one or more second dielectric layers comprise two or more second dielectric layers, and the first dielectric stack alternates between the two or more first dielectric layers and the two or more second dielectric layers.

24. The chip of clause 23, wherein the one or more third dielectric layers comprise two or more third dielectric layers, the one or more fourth dielectric layers comprise two or more fourth dielectric layers, and the second dielectric stack alternates between the two or more third dielectric layers and the two or more fourth dielectric layers.

25. The chip of any one of clauses 16 to 24, further comprising a backside interlayer dielectric (BS-ILD) extending under the first dielectric stack, the epi layer, and the second dielectric stack, wherein the backside contact extends through the BS-ILD.

26. The chip of any one of clauses 16 to 25, further comprising a backside rail, wherein the backside contact is coupled between the bottom surface of the epi layer and the backside rail.

27. The chip of clause 26, wherein the backside rail comprises a positive supply rail or a ground rail.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. At least one of A, B, and C means A, B, C, AB, BC, AC, or ABC.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first epitaxial (epi) layer;
a second epi layer;
a gate between the first epi layer and the second epi layer;
one or more channels coupled between the first epi layer and the second epi layer, wherein the one or more channels pass through the gate; and
a dielectric stack under the gate, the dielectric stack including:
one or more first dielectric layers; and
one or more second dielectric layers.

2. The chip of claim 1, further comprising a backside contact coupled to a bottom surface of the first epi layer.

3. The chip of claim 1, wherein the gate comprises a high-k (HK) dielectric material and a gate metal, and each of the one or more first dielectric layers comprises the HK dielectric material.

4. The chip of claim 3, wherein a thickness of each of the one or more first dielectric layers is equal to or less than twice a thickness of the HK dielectric material in the gate.

5. The chip of claim 3, wherein the HK dielectric material comprises at least one of Hafnium Oxide (HfO₂), Zirconium Oxide (ZrO₂), Aluminum Oxide (Al₂O₃), Tantalum Pentoxide (Ta₂O₅), Lanthanum Oxide, Titanium oxide (TiO₂), Yttrium(III) Oxide (Y₂O₃), and Lanthanum Doped Zirconium Oxide (LaZrO₂).

6. The chip of claim 1, further comprising:
a first gate spacer; and
a second gate spacer, wherein a portion of the gate is disposed between the first gate spacer and the second gate spacer.

7. The chip of claim 6, wherein each of the one or more second dielectric layers comprises a same dielectric material as the first gate spacer and the second gate spacer.

8. The chip of claim 7, wherein the dielectric material comprises at least one of silicon nitride (SiN), silicon dioxide (SiO₂), silicon carbonitride (SiCN), silicon oxycarbonitride (SiOCN), and carbon-doped silicon oxide (SiCOH).

9. The chip of claim 1, wherein the one or more first dielectric layers comprise two or more first dielectric layers, the one or more second dielectric layers comprise two or more second dielectric layers, and the dielectric stack alternates between the two or more first dielectric layers and the two or more second dielectric layers.

10. The chip of claim 1, wherein a width of the gate is approximately equal to a width of the dielectric stack.

11. The chip of claim 1, further comprising a backside interlayer dielectric (BS-ILD) extending under the dielectric stack and the first epi layer.

12. The chip of claim 11, further comprising a backside contact extending through the BS-ILD, wherein the backside contact is coupled to a bottom surface of the first epi layer.

13. The chip of claim 12, further comprising a backside rail, wherein the backside contact is coupled between the bottom surface of the first epi layer and the backside rail.

14. A chip, comprising:
a first gate;
a second gate;
an epitaxial (epi) layer between the first gate and the second gate;
a first dielectric stack under the first gate, the first dielectric stack including:
one or more first dielectric layers; and
one or more second dielectric layers;
a second dielectric stack under the second gate, the second dielectric stack including:
one or more third dielectric layers; and
one or more fourth dielectric layers; and
a backside contact extending between the first dielectric stack and the second dielectric stack, wherein the backside contact is coupled to a bottom surface of the first epi layer.

15. The chip of claim 14, wherein each of the first gate and the second gate comprises a high-k (HK) dielectric material and a gate metal, and each of the one or more first dielectric layers and each of the one or more third dielectric layers comprises the HK dielectric material.

16. The chip of claim 14, further comprising:
a first gate spacer; and
a second gate spacer, wherein a portion of the first gate is disposed between the first gate spacer and the second gate spacer.

17. The chip of claim 16, wherein each of the one or more second dielectric layers and each of the one or more fourth dielectric layers comprises a same dielectric material as the first gate spacer and the second gate spacer.

18. The chip of claim 14, wherein a width of the first gate is approximately equal to a width of the first dielectric stack, and a width of the second gate is approximately equal to a width of the second dielectric stack.

19. The chip of claim 14, wherein the one or more first dielectric layers comprise two or more first dielectric layers, the one or more second dielectric layers comprise two or more second dielectric layers, and the first dielectric stack alternates between the two or more first dielectric layers and the two or more second dielectric layers.

20. The chip of claim 19, wherein the one or more third dielectric layers comprise two or more third dielectric layers, the one or more fourth dielectric layers comprise two or more fourth dielectric layers, and the second dielectric stack alternates between the two or more third dielectric layers and the two or more fourth dielectric layers.
